(19) United States
(12) Patent Application Publication
(10) Pub. No.: US 2013/0021050 A1
(43) Pub. Date: Jan. 24, 2013

(54) Resonant test probe for integrated circuits

(71) Applicants: Ka Ng Chui, Menlo Park, CA (US); Wang Zhili, Fengtai District (CN)

(72) Inventors: Ka Ng Chui, Menlo Park, CA (US); Wang Zhili, Fengtai District (CN)

(73) Assignee: Corad Technology Inc., Santa Clara, CA (US)

(21) Appl. No.: 13/137,084

(22) Filed: Jul. 20, 2011

(51) Int. Cl. G01R 31/20

(52) U.S. Cl. 324/754.03

(57) ABSTRACT

A resonant test probe for testing high-speed integrated circuit devices. The test probe includes a probe tip that makes electrical contact with a device under test to receive a test signal from the device, and an output circuit transmits the received test signal to a testing apparatus. The test probe also includes tuning circuitry coupled between the probe tip and the output circuit. The tuning circuitry is configured to tune a resonance frequency of the test probe to be substantially equal to an operating frequency of the device under test to enable the test probe to transmit the test signal to the device under test.

### TECHNICAL FIELD

The present invention relates generally to integrated circuit technology and specifically to the testing of radio frequency (RF) signaling in integrated circuits.

### BACKGROUND OF RELATED ART

Probe cards are typically used in the testing of integrated circuit (IC) devices. Due to their design, probe cards are particularly advantageous for testing entire semiconductor wafers to detect any manufacturing defects before they are diced and packaged. For example, a probe card is typically formed from a printed circuit board (PCB) having a number of electrical contact elements disposed thereon. Each electrical contact element includes a probe tip which, during testing operations, is brought into contact with a device under test (DUT) and transmits electrical signals to and from the DUT. The probe card is additionally connected to an external testing apparatus which generates and/or analyzes the electrical signals transmitted through the DUT.

Because the probe tips serve as the interface between the DUT and the rest of the probe card, they are typically bound by numerous constraints. For example, the probe tip is often designed to bend or flex when making physical contact with the DUT so that a secure electrical connection can be established without damaging either the tip or the DUT. The flexibility of the probe tip typically also depends on the length of the tip, as a longer tip tends to be more flexible than a shorter one. However, a shorter probe tip will have a lower inductance, which is often desirable for high speed signaling. The length of the probe tips is further limited by technological constraints in their manufacturing processes.

The probe tip must be made of a conductive material (e.g., tungsten, beryllium copper, or other metal) in order to deliver an electrical signal to and from the DUT. However, probe tips typically have inductances and capacitances that adversely affect the transmission of electrical signals. For example, the inductance of the probe tip opposes changes in current, while the capacitance of the probe tip opposes changes in voltage. Signal loss may further be caused by radiation through air as the electrical signal propagates through the length of the probe tip. The inductances and capacitances of probe tips are especially problematic for signals with very short wavelengths (e.g., in the RF or microwave frequency range), as the high frequency signal may be entirely negated by the inductance and/or capacitance of the probe tip. This problem is further compounded by additional circuitry in the probe card carrying the signal from the probe tip to the testing apparatus.

Accordingly, there is a need to improve the testing capabilities of probe cards for high speed IC devices. More specifically, there is a need to increase the accuracy and reliability of test probe measurements without sacrificing the structural integrity of either the probe tip or the IC device.

### BRIEF DESCRIPTION OF THE DRAWINGS

The present embodiments are illustrated by way of example and not intended to be limited by the figures of the accompanying drawings, where:

FIG. 1A shows a resonant test probe, according to an embodiment;

FIG. 1B shows a resonant test probe, according to another embodiment;

FIG. 2A illustrates a more detailed embodiment of the resonant test probe shown in FIG. 1A;

FIG. 2B illustrates a more detailed embodiment of the resonant test probe shown in FIG. 1B;

FIG. 3A illustrates an alternative embodiment of the resonant test probe shown in FIG. 1A;

FIG. 3B illustrates an alternative embodiment of the resonant test probe shown in FIG. 1B;

FIG. 4A illustrates another embodiment of the resonant test probe shown in FIG. 1A;

FIG. 4B is a side profile view of the resonant test probe shown in FIG. 4A;

FIG. 5A illustrates another embodiment of the resonant test probe shown in FIG. 1B;

FIG. 5B is a side profile view of the resonant test probe shown in FIG. 5A;

FIG. 6 shows a system for testing a high speed IC device, according to an embodiment;

FIG. 7 shows a system for testing a high speed IC device, according to another embodiment;

FIG. 8 is a flowchart illustrating an operation for testing high speed IC devices, according to an embodiment;

Like reference numerals refer to corresponding parts throughout the drawing figures.

### DETAILED DESCRIPTION

A method and apparatus for testing high speed integrated circuit (IC) devices are disclosed. In the following description, for purposes of explanation, specific nomenclature is set forth to provide a thorough understanding of the present invention. However, it will be apparent to one skilled in the art that these specific details may not be required to practice the present invention. In other instances, well-known circuits and devices are shown in block diagram form to avoid obscuring the present invention unnecessarily. Additionally, the interconnection between circuit elements or blocks may be shown as buses or as single signal lines. Each of the buses may alternatively be a single signal line, and each of the single signal lines may alternatively be a bus. As used herein, references to “adjust” or “adjusting” may refer to either modifying the characteristics of an existing circuit element or controlling the parameters of a circuit element to be created. Accordingly, the present invention is not to be construed as limited to specific examples described herein but rather includes within its scope all embodiments defined by the appended claims.

Present embodiments allow for the testing of high-speed IC devices. A resonant test probe is capable of picking up high frequency test signals in an IC device and communicating the test signals to a testing apparatus. In specific embodiments, a resonant test probe includes tuning circuitry that is configured to enable the test probe to have a resonant frequency substantially equal to an operating frequency of the device under test (DUT). In some embodiments, a signal transmitted through the resonant probe is attenuated by a substantially constant amount, so that the amount of attenuation can be used to accurately measure the signal response of the DUT. In other embodiments, the resonant test probe includes shielding to isolate the circuitry from external noise and interference. The resonant test probe described herein can be implemented with only minor modifications to existing probe card technology.

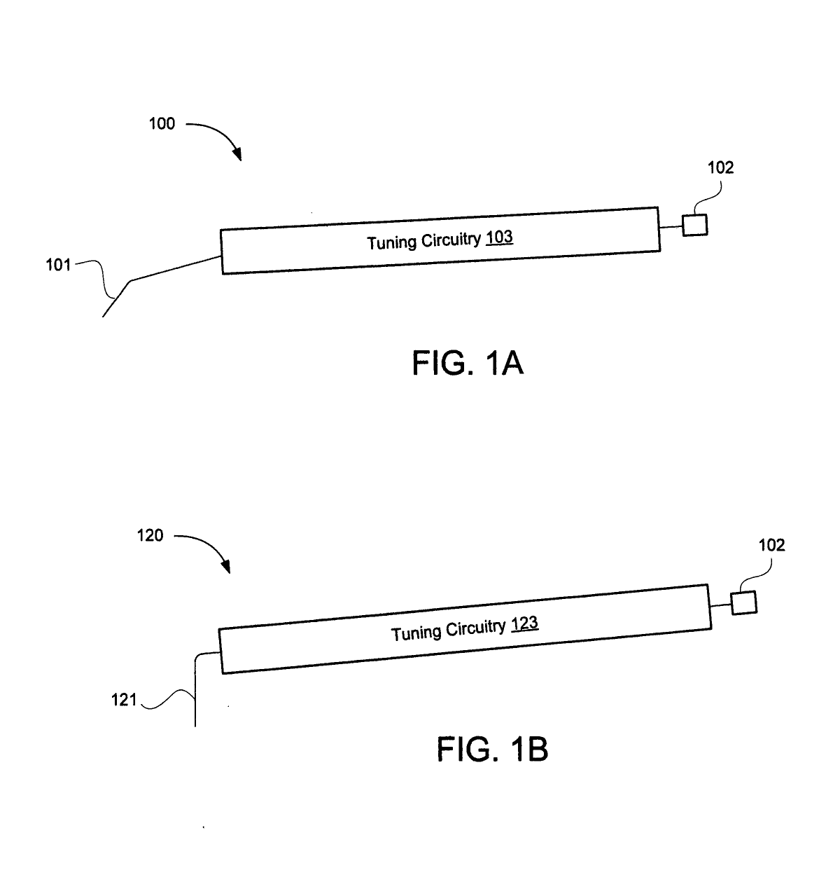

FIG. 1A shows a resonant test probe, according to an embodiment. The test probe 100 includes a probe tip 101, a connector interface 102, and tuning circuitry 103. The probe tip 101 is made of a conductive material and configured to make contact with an IC device (or DUT) to transmit and/or receive a test signal. The connector interface 102 connects the test probe 100 to a testing apparatus (e.g., automatic test equipment or “ATE”). Specifically, the connector interface 102 communicates the transmitted and/or received test signal to and from the testing apparatus. In some embodiments, the probe tip 101 and the connector interface 102 are well known. For example, the probe tip 101 may be a cantilever style probe tip designed to make contact with the DUT at an angle. The connector interface 102 may be, for example, a SMP, SMA or other type of interface that can be connected to the testing apparatus via a coaxial cable.

The tuning circuitry 103 is a conductive medium coupled between the probe tip 101 and the connector interface 102, and is configured to facilitate the transmission of a high-speed test signal to and from the DUT. For some embodiments, the tuning circuitry 103 enables the test probe 100 to have a resonance frequency substantially equal to that of an operating frequency of the DUT. In other words, the tuning circuitry 103 is configured such that the test probe 100 exhibits electrical resonance when a high-speed (e.g., radio frequency) test signal is transmitted to and/or received from the DUT. For example, the probe tip 101 and the connector interface 102, and even the tuning circuitry 103, all have inductances and capacitances that adversely affect the transmission of electrical signals. However, by “tuning” the resonance frequency of the test probe 100 to the operating frequency of the DUT, the tuning circuitry 103 enables the test probe 100 to transmit electrical signals at frequencies that would otherwise be filtered out by one or more inductances and capacitances of the test probe 100. Specifically, the tuning circuitry 103 may allow for accurate testing of IC devices operating in the RF frequency range (e.g., 1 GHz).

For some embodiments, the tuning circuitry 103 comprises a length of wire made of a conducting material (e.g., copper). The length of the wire is determined so that the test probe 100 has a resonance frequency substantially equal to an operating frequency of the DUT (e.g., corresponding to the frequency of test signals transmitted to and/or from the DUD. For specific embodiments, the length of the wire is substantially equal to N*(λ/4), where λ is the wavelength of the test signal and N is any integer value. Alternatively, a testing apparatus (e.g., a vector network analyzer) may be used to precisely tune the tuning circuitry 103 so that the resonance frequency of the test probe is substantially equal to the operating frequency of the device under test.

FIG. 1B shows a resonant test probe, according to another embodiment. The test probe 120 includes a probe tip 121, a connector interface 102, and tuning circuitry 123. The probe tip 121 is a vertical style probe tip, made of a conductive material and configured to make contact with a DUT at a 90° angle to transmit and/or receive a test signal. Embodiments of the vertical probe tip 121 are also well known. Due to its geometry and contact angle with the DUT, the probe tip 121 can be made much shorter than the cantilever style probe tip 101.

The tuning circuitry 123 is coupled between the probe tip 121 and the connector interface 102, and operates in a similar manner as the tuning circuitry 103 described above. However, because the vertical-style probe tip 121 may be shorter than cantilever-style probe tip 101, the tuning circuitry 123 may be longer in length than the tuning circuitry 103. Specifically, the tuning circuitry 123 may allow for accurate testing of IC devices operating in the RF frequency range (e.g., 1 GHz)

For some embodiments, the tuning circuitry 123 comprises a length of wire made of a conducting material (e.g., copper). The length of the wire is determined so that the test probe 120 has a resonance frequency substantially equal to an operating frequency of the DUT (e.g., corresponding to the frequency of test signals transmitted to and/or from the DUT). For specific embodiments, the length of the wire is substantially equal to N*(λ/4), where λ is the wavelength of the test signal and N is any integer value. Alternatively, a testing apparatus (e.g., a vector network analyzer) may be used to precisely tune the tuning circuitry 103 so that the resonance frequency of the test probe is substantially equal to the operating frequency of the DUT.

Note that, in some embodiments, the test probes 100 and 120 may be configurable and/or programmable to facilitate the testing of IC devices having various operating frequencies. For example, the tuning circuits 103 and 123 may be “tuned” so that the respective test probes 100 and 120 have resonance frequencies substantially equal to that of the DUT. For some embodiments, each of the tuning circuits 103 and 123 may be tuned by adjusting a length of wire within a respective one of the tuning circuits 103 and 123. Furthermore, although cantilever and vertical style probe tips have been specifically described, the tuning circuitry can be easily modified for any probe tip geometry, according to additional embodiments.

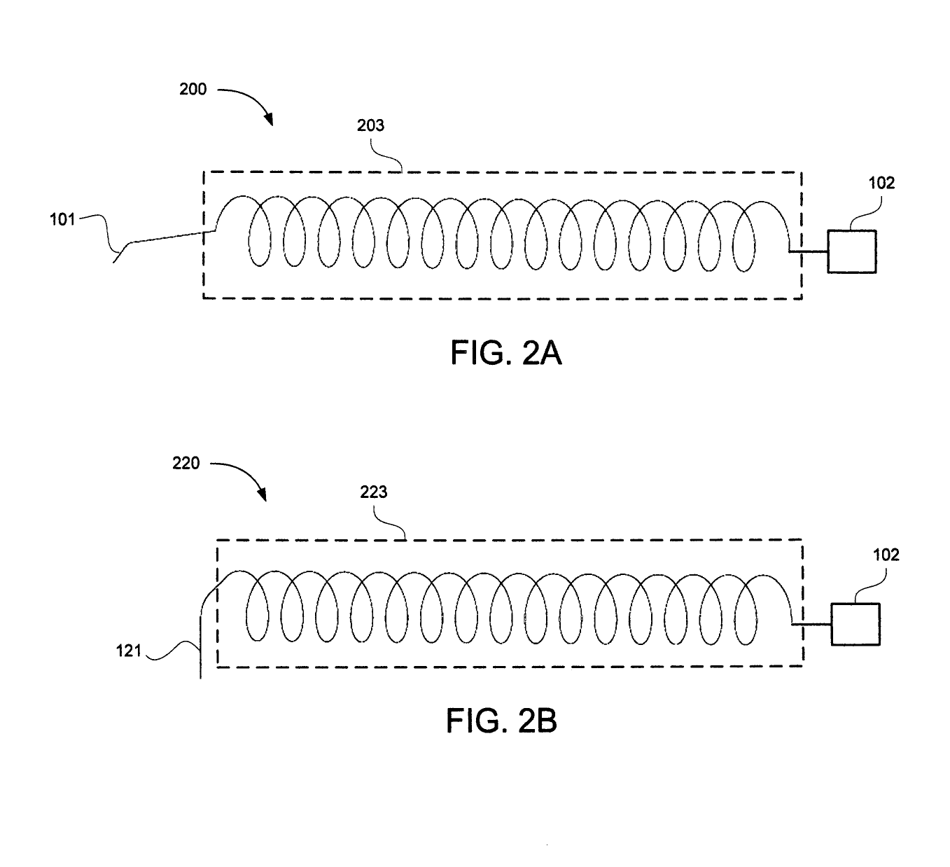

FIG. 2A shows a more detailed embodiment of the resonant test probe shown if FIG. 1A. The resonant test probe 200 includes probe tip 101, output circuit 102, and tuning circuitry 203. As discussed above, the tuning circuitry 203 may comprise a length of conductive wire (e.g., copper). According to a specific embodiment, the tuning circuitry 203 comprises a coiled wire. In coiled form, the wire reduces the footprint of the tuning circuitry 203. The tuning circuitry 203 can be tuned, for example, by adjusting the length of the coiled wire (e.g., by trimming the wire) so that the test probe 200 has a resonance frequency that is substantially equal to an operating frequency of the DUT. For specific embodiments, the overall length of the resonant test probe 200 is substantially equal to N*(λ/4), where λ is the wavelength of the test signal and N is any integer value. Alternatively, a testing apparatus (e.g., a vector network analyzer) may be used to precisely tune the tuning circuitry 203 so that the resonance frequency of the test probe is substantially equal to the operating frequency of the DUT.

FIG. 2B shows a more detailed embodiment of the resonant test probe shown in FIG. 1B. The resonant test probe 220 includes probe tip 121, output circuit 102, and tuning circuitry 223. The tuning circuitry 223 operates in a similar manner as described above, with reference to the tuning circuitry 203 of FIG. 2A, and can therefore be used to reduce the footprint of the resonant test probe 220. However, because the probe tip 121 is a vertical style probe tip, the coiled wire of the tuning circuitry 223 may be longer in overall length than the coil in the tuning circuitry 203. The tuning circuitry 223 can be tuned, for example, by adjusting the length of the coiled wire so that the test probe 220 has a resonance frequency that is substantially equal to an operating frequency of the DUT. For specific embodiments, the overall length of the resonant test probe 220 is substantially equal to N*(λ/4), where λ is the wavelength of the test signal and N is any integer value. Alternatively, a testing apparatus (e.g., a vector network analyzer) may be used to precisely tune the tuning circuitry 223 so that the resonance frequency of the test probe is substantially equal to the operating frequency of the DUT.

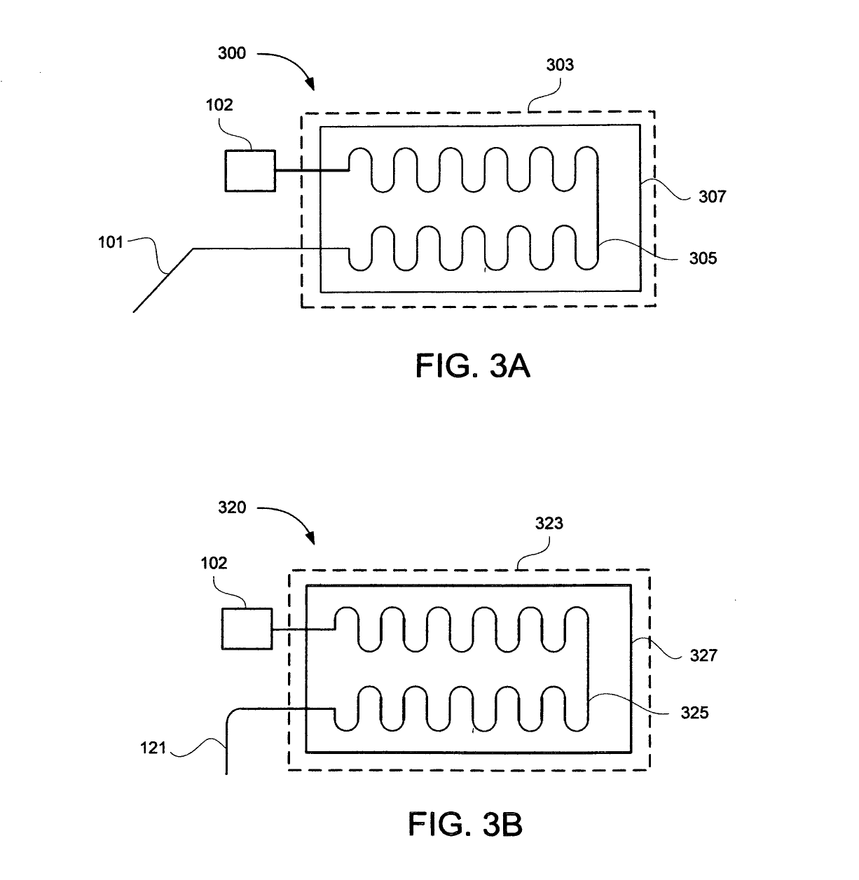

FIG. 3A shows an alternative embodiment of the test probe shown in FIG. 1A. The resonant test probe 300 includes probe tip 101, output circuit 102, and tuning circuitry 303. The tuning circuitry 303 further comprises a conductive trace 305 disposed on a printed circuit board (PCB) 307. The PCB 307 may, for example, correspond to the PCB portion of a probe card, or at least a portion thereof. Accordingly, the tuning circuitry 303 may be constructed by etching the conductive trace 305 onto a surface of the PCB 307, thus allowing the tuning circuitry 303 to be integrally formed with the PCB portion of a probe card. The tuning circuitry 303 can be tuned, for example, by adjusting the length and/or other dimensions of the conductive trace 305 so that the test probe 300 has a resonance frequency that is substantially equal to an operating frequency of the DUT. For specific embodiments, the overall length of the resonant test probe 300 is substantially equal to N*(λ/4), where λ is the wavelength of the test signal and N is any integer value. Alternatively, a testing apparatus (e.g., a vector network analyzer) may be used to precisely tune the tuning circuitry 303 so that the resonance frequency of the test probe is substantially equal to the operating frequency of the DUT.

FIG. 3B shows an alternative embodiment of the resonant test probe shown in FIG. 1B. The resonant test probe 320 includes probe tip 121, output circuit 102, and tuning circuitry 323. The tuning circuitry 323 further comprises a conductive trace 325 disposed on a PCB 327, and operates in a similar manner as described above, with reference to the tuning circuitry 303 of FIG. 3A. Thus, the tuning circuitry 323 can also be integrally formed with the PCB portion of a probe card. The tuning circuitry 323 can be tuned, for example, by adjusting the length and/or other dimensions of the conductive trace 325 so that the test probe 320 has a resonance frequency that is substantially equal to an operating frequency of the DUT. However, because the probe tip 121 is a vertical style probe tip, the conductive trace 325 may have even larger dimensions than the conductive trace 305. For specific embodiments, the overall length of the resonant test probe 320 is substantially equal to N*(λ/4), where λ is the wavelength of the test signal and N is any integer value. Alternatively, a testing apparatus (e.g., a vector network analyzer) may be used to precisely tune the tuning circuitry 323 so that the resonance frequency of the test probe is substantially equal to the operating frequency of the device under test.

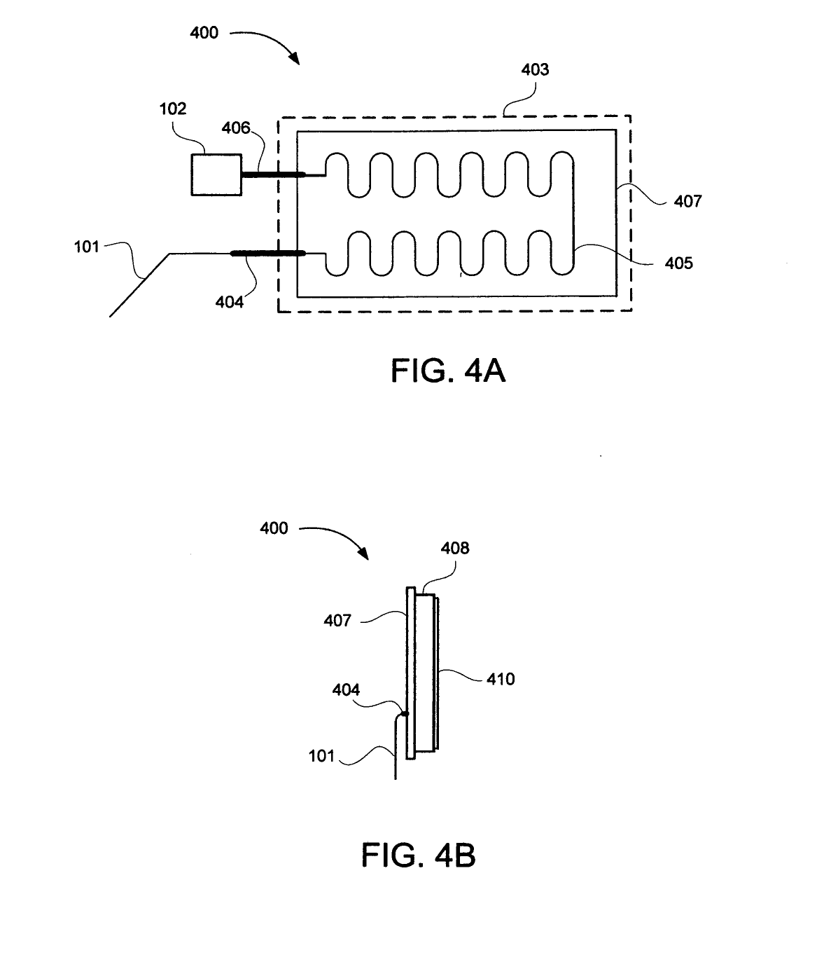

FIGS. 4A and 4B illustrate another embodiment of the resonant test probe shown in FIG. 1A. The resonant test probe 400 includes probe tip 101, output circuit 102, tuning circuitry 403, and a set of shielding elements 404 and 406. The first shielding element 404 shields the connection between the probe tip 101 and the tuning circuitry 403 from unwanted noise and interference, thus improving signal quality. Likewise, the second shielding element 406 shields the connection between the output circuit 102 and the tuning circuitry 403 from external interference. According to an embodiment, the tuning circuitry 403 may be connected to each of the probe tip 101 and the output circuit 102 via a coaxial wire. Thus, the first and second shielding elements 404 and 406 may correspond to the outer layer (and/or sheath) of the coaxial wire.

Tuning circuitry 403 comprises a conductive trace 405 disposed on a PCB 407. A metallic shield 410 is provided on the backside of the PCB 407 to shield the conductive trace 405 from external noise and interference. A dielectric layer 408 is sandwiched between the metallic shield 410 and the PCB 407. The type and thickness of a dielectric used to form dielectric layer 408 may affect the capacitive and/or inductive properties of the conductive trace 405, and thus provides an additional layer of tuning for the tuning circuitry 403. Thus, the tuning circuitry 403 may be tuned, for example, by adjusting the dimensions of the conductive trace 405 as well as the thickness and/or material of the dielectric layer 408. According to an embodiment, the PCB 407 is made from a flexible PCB material and the dielectric layer 408 comprises a more rigid PCB, thus providing additional structural support for the tuning circuitry 403. Alternatively, the tuning circuitry 403 may be integrally formed with the PCB portion of a corresponding probe card. For example, the PCB 407 may correspond to the PCB portion of a probe card, or at least a portion thereof.

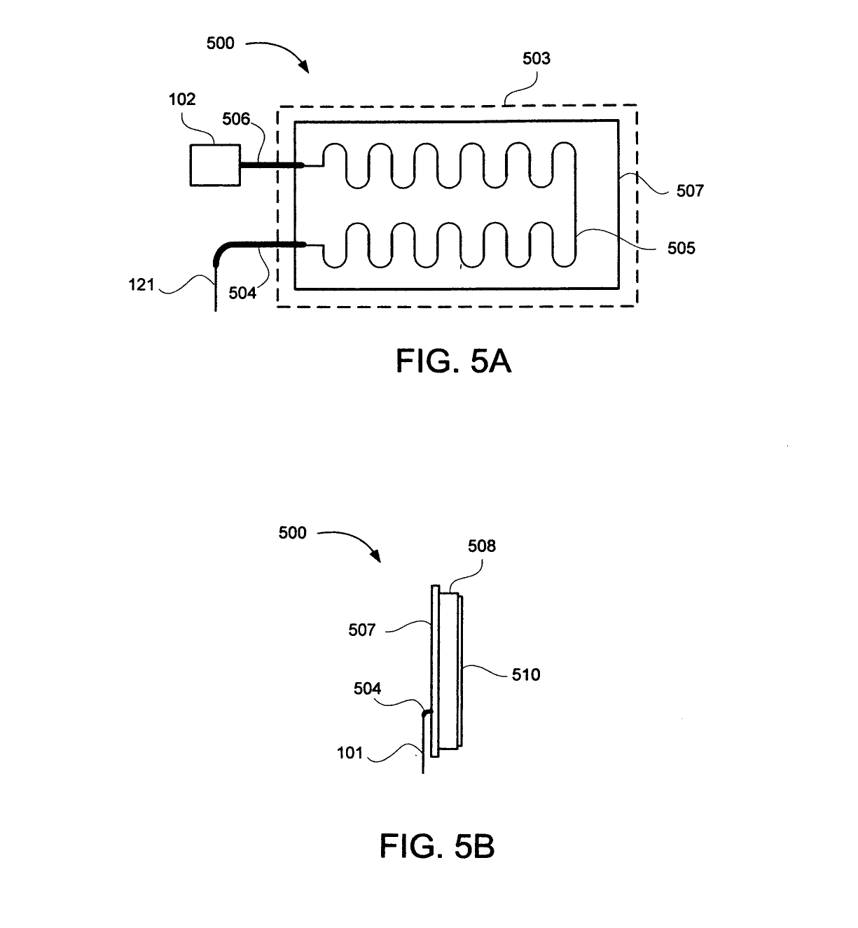

FIGS. 5A and 5B illustrate another embodiment of the resonant test probe shown in FIG. 1B. The resonant test probe 500 includes probe tip 121, output circuit 102, tuning circuitry 503, and a set of shielding elements 504 and 506. The first shielding element 504 shields the connection between the probe tip 121 and the tuning circuitry 503 from unwanted noise and interference. Likewise, the second shielding element 506 shields the connection between the output circuit 102 and the tuning circuitry 503 from external interference. According to an embodiment, the tuning circuitry 503 may be connected to each of the probe tip 121 and the output circuit 102 via a coaxial wire. Thus, the first and second shielding elements may 504 and 506 may correspond to the outer layer (and/or sheath) of the coaxial wire.

Tuning circuitry 503 comprises a conductive trace 505 disposed on a PCB 507. A metallic shield 510 is provided on the backside of the PCB 507 to shield the conductive trace 505 from external noise and interference. A dielectric layer 508 is sandwiched between the metallic shield 510 and the PCB 507. The tuning circuitry 503 may be tuned in a similar manner as the tuning circuitry 403, described above with reference to FIGS. 4A-4B (e.g., by adjusting the dimensions of the conductive trace 505 and/or the thickness or material of the dielectric layer 508). In addition, the shorter vertical style probe tip 121 may allow the tuning circuitry 503 to be tuned differently than the tuning circuitry 403. According to an embodiment, the PCB 507 is made from a flexible PCB material and the dielectric layer 508 comprises a more rigid PCB to provide additional structural support for the tuning circuitry 503. Alternatively, the tuning circuitry 503 may be integrally formed with the PCB portion of a corresponding probe card.

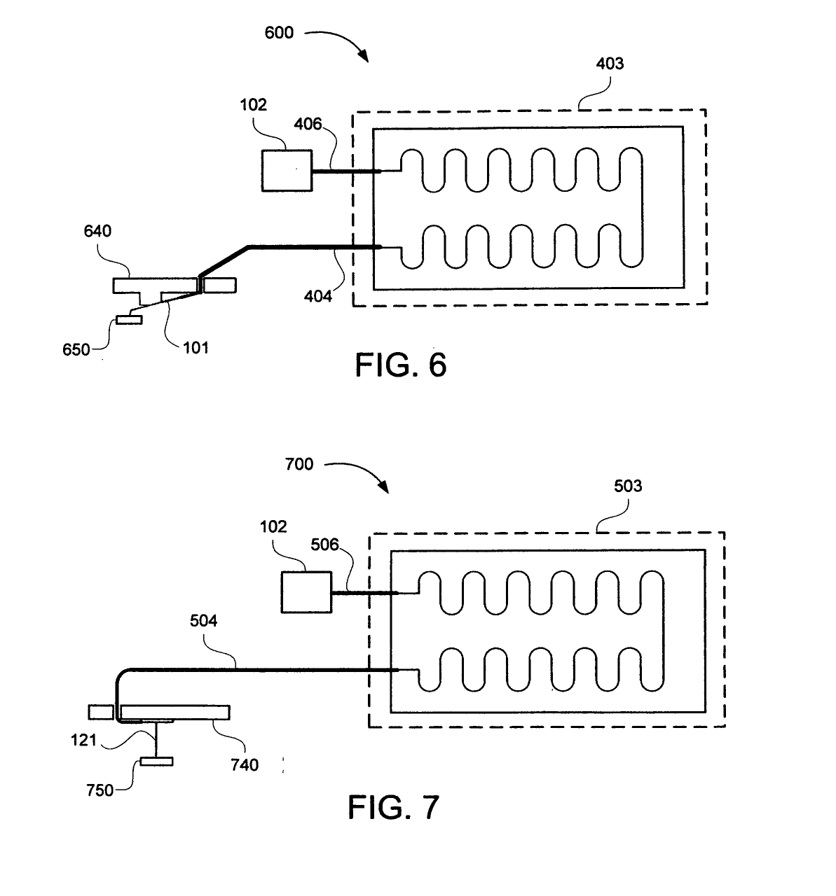

FIG. 6 illustrates a system for testing a high speed IC device, according to an embodiment. The system 600 includes probe tip 101, output circuit 102, tuning circuitry 403, a probe card 640, and a DUT 650. As discussed above, the probe tip 101, output circuit 102, and tuning circuitry 403 collectively form a resonant test probe according to embodiments described herein. The DUT 650 may be an integrated circuit die on a wafer (e.g., prior to dicing). The probe card 640 interfaces the probe tip 101 with the DUT 650 for testing purposes. Specifically, the probe card 640 may comprise a PCB which couples to the probe tip 101, to hold the probe tip 101 at an angle over the surface of DUT 650. The tuning circuitry 403 is coupled to the probe tip 101 via a hole in the probe card 640. In the embodiment shown, the system 600 includes shielding elements 404 and 406 coupled to the connections between the tuning circuitry 403 and each of the probe tip 101 and the output circuit 102. Alternatively, however, the connections between the tuning circuitry 403, the probe tip 101, and the output circuit 102, may be formed using an unshielded conductive (e.g., copper) wire. In other embodiments, the tuning circuitry 403 may be integrally formed with the probe card 640.

When measuring or detecting a test signal from the DUT 650, a testing apparatus (e.g., an ATE) is coupled to the output circuit 102, and the probe tip 101 is brought into contact with an output contact pad of the DUT 650 by manipulating the probe card 640. The test signal in the DUT 650 is picked up by the probe tip 101 and routed, through the tuning circuitry 403 and the output circuit 102, to the testing apparatus. Again, the tuning circuitry 403 causes the resonant test probe (e.g., comprising output circuit 102, tuning circuitry 403, and probe tip 101) to exhibit electrical resonance in response to the received test signal. The tuning circuitry 403 thus enables the testing apparatus to receive and accurately test the signal response of the DUT 650 for very high (e.g., RF) frequencies, for example, by adding the amount of signal loss through the resonant test probe (e.g., the “attenuation factor,” which may be a predetermined quantity) to the signal response detected by the testing apparatus. If the detected test signal is not substantially equal to the output signal after accounting for the attenuation factor, then this may be indicative of a problem with the DUT 650.

The system 600 may be further used to determine the attenuation factor of the resonant test probe (e.g., comprising output circuit 102, tuning circuitry 403, and probe tip 101). For example, a signal generator may be connected, via another probe tip (not shown) coupled to the probe card 640, to a pad of the DUT 650 to transmit a test signal at the desired frequency to the probe tip 101. The probe tip 101 is also connected to a pad of the DUT 650, and a spectrum analyzer or power meter is connected to the output circuit 102 to receive a signal response from the probe tip 101. The attenuation factor for the resonant test probe may then be determined by comparing the received signal at the spectrum analyzer or power meter with the output signal output by the signal generator. The total attenuation may depend on a number of factors, including one or more inductances and capacitances along the transmission path of the resonant test probe and signal loss due to radiation through air. However, after tuning the test probe to exhibit electrical resonance at the frequency of the test signal, the total attenuation of a test signal transmitted (or received) through the test probe is limited to a substantially consistent amount (e.g., −13 dBm). In other words, repeat tests using the resonant test probe will yield very little variation in the amount of attenuation in a received test signal (e.g., <1 dBm). Accordingly, the attenuation factor is precise enough to determine whether the DUT 650 is defective simply by adding the attenuation factor to the measured signal response of the DUT 650 and comparing it against the output signal.

Note that the DUT 650 is not necessary for determining the attenuation factor. For example, when finding the attenuation factor, the DUT 650 simply serves the purposes of a conductor (e.g., to communicate the test signal to the probe tip 101). Accordingly, in alternative embodiments, the DUT 750 may be replaced with a conductive plate or trace. Furthermore, the attenuation factor may be a predetermined value (e.g., determined upon manufacturing the resonant test probe) and provided to a user of the test probe. For purposes of illustration, only one probe tip 101 is shown coupled to the probe card 640. However, the probe card 640 may in fact include a number of probe tips 101 (and corresponding tuning circuitry 403 and output circuits 102) for purposes of transmitting and/or receiving test signals to and from multiple wafer contact pads, concurrently.

FIG. 7 illustrates a system for testing a high speed IC device, according to another embodiment. The system 700 includes probe tip 121, output circuit 102, tuning circuitry 503, a probe card 740, and a DUT 750. The DUT 750 may have contact pads arranged in a pattern (e.g., an array) that would otherwise be unreachable by one or more of the cantilever style probe tips 101, which are typically arranged in ring or circular configuration. However, the vertical style probe tip 121 can be arranged in an optimal configuration (e.g., an array) to reach each of the contact pads of the DUT 750. The probe card 740 interfaces the probe tip 121 with the DUT 750 for testing purposes. Specifically, the probe card 740 may comprise a PCB which couples to the probe tip 121, to hold the probe tip 121 vertically above the DUT 750. The tuning circuitry 503 is coupled to the probe tip 121 via a hole in the probe card 740. In the embodiment shown, the system 700 includes shielding elements 504 and 506 coupled to the connections between the tuning circuitry 503 and each of the probe tip 121 and the output circuit 102. Alternatively, however, the connections between the tuning circuitry 503, the probe tip 121, and the output circuit 102 may be formed using an unshielded conductive wire. In other embodiments, the tuning circuitry 503 may be integrally formed with the probe card 740.

When measuring or detecting a test signal from the DUT 750, a testing apparatus (e.g., an ATE) is coupled to the output circuit 102, and the probe tip 121 is brought into contact with an output contact pad of the DUT 750 by manipulating the probe card 740. The test signal in the DUT 750 is picked up by the probe tip 121 and routed, through the tuning circuitry 503 and the output circuit 102, to the testing apparatus. Again, the tuning circuitry 503 causes the resonant test probe (e.g., comprising output circuit 102, tuning circuitry 503, and probe tip 121) to exhibit electrical resonance in response to the received test signal. The tuning circuitry 503 thus enables the testing apparatus to receive and accurately test the signal response of the DUT 750 for very high (e.g., RF) frequencies, for example, by adding the attenuation factor associated with the test probe to the signal response detected by the testing apparatus.

The system 700 may be further used to determine the attenuation factor of the resonant test probe (e.g., comprising output circuit 102, tuning circuitry 503, and probe tip 121). For example, a signal generator may be connected, via another probe tip (not shown) coupled to the probe card 740, to a pad of the DUT 750 to transmit a test signal at the desired frequency to the probe tip 121. The probe tip 121 is also connected to a pad of the DUT 750, and a spectrum analyzer or power meter is connected to the output circuit 102 to receive a signal response from the probe tip 121. The attenuation factor for the resonant test probe may then be determined by comparing the received signal at the spectrum analyzer or power meter with the output signal output by the signal generator. The difference between the output signal and the received test signal yields the attenuation factor, which is a substantially consistent and precise value.

Note that the DUT 750 is not necessary for determining the attenuation factor. For example, when finding the attenuation factor, the DUT 750 simply serves the purposes of a conductor (e.g., to communicate the test signal to the probe tip 121). Accordingly, in alternative embodiments, the DUT 750 may be replaced with a conductive plate or trace. Furthermore, the attenuation factor may be a predetermined value (e.g., determined upon manufacturing the resonant test probe) and provided to a user of the test probe. For purposes of illustration, only one probe tip 121 is shown coupled to the probe card 740. However, the probe card 740 may in fact include a number of probe tips 121 (and corresponding tuning circuitry 503 and output circuits 102) for purposes of transmitting and/or receiving test signals to and from multiple wafer contact pads, concurrently.

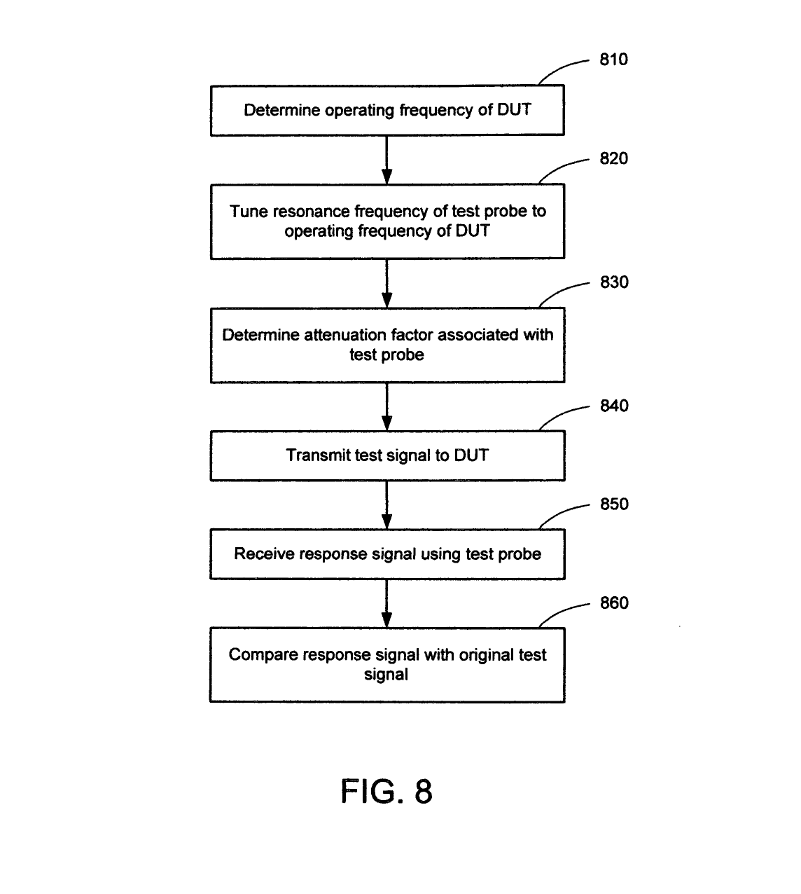

FIG. 8 illustrates a method of operating a resonant test probe, according to an embodiment. An operating frequency of a DUT is first determined, 810. The operating frequency is typically known, however, it may also be determined by testing the signal response of the DUT (e.g., at various frequencies). Then, at 820, the resonant test probe is tuned to have a resonance frequency substantially equal to the operating frequency of the DUT. The resonant test probe may be tuned, for example, by adjusting the characteristics of tuning circuitry within the test probe (e.g., as described in any of the embodiments above). The attenuation factor associated with the test probe is then determined, at 830. The attenuation factor can be determined, for example, by coupling a spectrum analyzer or power meter to the resonant test probe and using the resonant test probe to measure a signal transmitted through a properly functioning DUT. Alternatively, the attenuation factor may be a predetermined value associated with the resonant test probe.

A test signal is transmitted to the DUT, at 840, and a signal response is subsequently determined for the DUT, at 850. The signal response may be determined, for example by coupling an ATE to the resonant test probe and bringing a probe tip of the resonant test probe into contact with the DUT to receive a response signal from the DUT. Then, at 860, the response signal is compared against the output signal transmitted to the DUT to determine whether the DUT is properly functioning. For example, the ATE may be programmed to output a predetermined sequence of test patterns of varying amplitudes (e.g., “Hi” and “Lo” values) to the DUT. If, after accounting for the attenuation factor (e.g., adding the attenuation factor to the response signal), the response signal is substantially within range of the Hi and Lo specifications of the output signal, then the DUT is likely functioning properly. Otherwise, the DUT may be defective. The range may, for example, correspond to a margin of error in the determination of the attenuation factor.

While particular embodiments have been shown and described, it will be obvious to those skilled in the art that changes and modifications may be made without departing from this disclosure in its broader aspects and, therefore, the appended claims are to encompass within their scope all such changes and modifications as fall within the true spirit and scope of this disclosure.

Further, it should be noted that the various circuits disclosed herein may be described using computer aided design tools and expressed (or represented), as data and/or instructions embodied in various computer-readable media, in terms of their behavioral, register transfer, logic component, transistor, layout geometries, and/or other characteristics. Formats of files and other objects in which such circuit expressions may be implemented include, but are not limited to, formats supporting behavioral languages such as C, Verilog, and VHDL, formats supporting register level description languages like RTL, and formats supporting geometry description languages such as GDSII, GDSIII, GDSIV, CIF, MEBES and any other suitable formats and languages. Computer-readable media in which such formatted data and/or instructions may be embodied include, but are not limited to, non-volatile storage media in various forms (e.g., optical, magnetic or semiconductor storage media).

What is claimed is:

1. A test probe for testing integrated circuit (IC) devices, the test probe comprising:
a probe tip for making electrical contact with a device under test to receive a test signal from the device;
an output circuit to transmit the received test signal to a testing apparatus; and
tuning circuitry coupled between the probe tip and the output circuit, wherein the tuning circuitry is configured to tune a resonance frequency of the test probe to be substantially equal to an operating frequency of the device under test to enable the test probe to transmit the test signal to the testing apparatus.

2. The test probe of claim 1, wherein the tuning circuitry is configured to enable the test probe to exhibit electrical resonance in response to the test signal.

3. The test probe of claim 1, wherein the tuning circuitry comprises a conductive wire.

4. The test probe of claim 3, wherein the tuning circuitry comprises a coiled wire.

5. The test probe of claim 3, wherein the tuning circuitry is configured by adjusting a length of the conductive wire.

6. The test probe of claim 1, wherein the tuning circuitry comprises a conductive trace on a printed circuit board.

7. The test probe of claim 6, wherein the tuning circuitry is configured by adjusting one or more dimensions of the conductive trace.

8. The test probe of claim 6, wherein the printed circuit board is coupled to a dielectric material, and wherein the tuning circuitry is configured by changing at least one of a thickness or type of the dielectric material coupled to the printed circuit board.

9. The test probe of claim 6, wherein the tuning circuitry is integrally formed on a probe card device.

10. The test probe of claim 1, wherein the probe tip is a cantilever-style probe tip.

11. The test probe of claim 1, wherein the probe tip is a vertical-style probe tip.

12. The test probe of claim 1, wherein the test signal is a radio frequency (RF) signal, and wherein the resonance frequency of the test probe is greater than or equal to 1 GHz.

13. A method of operating a test probe for testing an IC device, the method comprising:
tuning a resonance frequency of the test probe to be substantially equal to an operating frequency of the IC device;
transmitting a test signal to the IC device; and
receiving a response signal from the IC device, wherein a frequency of the response signal is substantially equal to the operating frequency of the IC device.

14. The method of claim 13, further comprising comparing the response signal with the test signal transmitted to the IC device to determine whether the IC device functions properly.

15. The method of claim 14, further comprising determining an attenuation factor associated with the test probe.

16. The method of claim 15, wherein comparing the response signal with the test signal transmitted to the IC device comprises:
combining the attenuation factor with the received response signal to determine an adjusted response signal; and
determining whether an amplitude of the adjusted response signal is substantially equal to an amplitude of the test signal.

17. The method of claim 13, wherein tuning a resonance frequency of the test probe comprises adjusting a length of a transmission path in the test probe.

18. The method of claim 17, wherein adjusting a length of a transmission path includes adjusting the length of a conductive wire.

19. The method of claim 17, wherein adjusting a length of a transmission path includes adjusting the length of a conductive trace on a printed circuit board.

20. The test probe of claim 13, wherein the response signal is a radio frequency (RF) signal, and wherein the resonance frequency of the test probe is greater than or equal to 1 GHz.

21. A system for testing integrated circuit (IC) devices, the test probe comprising:
means for tuning a resonance frequency of the test probe to be substantially equal to an operating frequency of the IC device;
means for transmitting a test signal to the IC device; and
means for receiving a response signal from the IC device, wherein a frequency of the response signal is substantially equal to the operating frequency of the IC device.
